(19) United States
(12) Patent Application Publication
(10) Pub. No.: US 2008/0310108 A1
(43) Pub. Date: Dec. 18, 2008

(54) EXTERNAL HEAT SINK FOR ELECTRONIC DEVICE

(75) Inventors: Joakim Eriksson, Lund (SE); Bogdan Tudosoiu, Lund (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 11/762,425

(22) Filed: Jun. 13, 2007

(51) Int. Cl. H05K 7/20

(52) U.S. Cl. 361/697; 361/707; 361/709

(57) ABSTRACT

An external heat sink device that can be attached to an electronic device during periods of excess heat generation, such as during a gaming session, for example. The external heat sink device can be removed from the electronic device during times of relatively lower heat generation. Other external accessories can be associated with the external heat sink device, such as an external antenna, speakers, game input device, power supply, etc.

### TECHNICAL FIELD OF THE INVENTION

The present invention relates generally to electronic devices and, more particularly, to portable electronic devices.

### DESCRIPTION OF THE RELATED ART

In designing the physical characteristics of mobile phones, a number of considerations are taken into account. One characteristic that is particularly important to users of mobile phones is the size and/or thickness of the mobile phone (generally a smaller and/or thinner phone is preferred). Thus, a trend in mobile phones has generally been towards smaller and thinner mobile phones.

Conventional mobile phones, in addition to providing voice communication capabilities, also provide a number of non-voice related features. For example, mobile phones can be used to surf the internet, transmit and receive messages (e.g., emails and text messages), play music and videos, take and display photographs, as well as a number of other features.

An increasingly popular function of mobile phones is gaming. As mobile phone processors become more powerful, mobile phone games can be more advanced and become more graphics intensive. For example, three-dimensional (3D) gaming is becoming possible on mobile phones. Network gaming is also possible using the mobile phone's communication circuitry, for example, to connect the mobile phone to a gaming network.

During a 3D gaming session, and in particular a networked 3D gaming session, a mobile phone typically consumes an increased amount of power (e.g., max power) as compared to other mobile phone functions, such as placing a call, for example. Accordingly, the mobile phone typically generates an increased amount of heat during such activities. As mobile phones decrease in size, dissipating the heat generated by the phone becomes an increasing challenge.

### SUMMARY

To improve performance and reliability of mobile phones, particularly during periods of excess heat generation, while maintaining a sleek form factor desirable to consumers, there is a need for an external heat sink device that can be attached to the mobile phone during periods of excess heat generation, such as during a gaming session, for example. The external heat sink device can be removed from the phone during times of relatively lower heat generation. Other external accessories can be associated with the external heat sink device, such as an external antenna, speakers, game input device, power supply, etc.

In accordance with an aspect of the invention, an electronic device assembly comprises an electronic device having a housing, and a heat sink device releasably attachable to the housing of the electronic device for absorbing heat therefrom.

In accordance with another aspect of the invention, the electronic device includes communication circuitry, wherein the heat sink device includes an antenna element couplable to the communication circuitry when the heat sink device is attached to the electronic device.

In accordance with another aspect of the invention, the heat sink device includes a passive heat sink.

In accordance with another aspect of the invention, the passive heat sink is a heat sink including at least one cooling fin for dissipating heat into the environment.

In accordance with another aspect of the invention, the electronic device further comprises a thermoelectric cooling device contained within the housing of the electronic device, the thermoelectric cooling device configured to transfer heat from an interior of the housing to the exterior of the housing, wherein the heat sink device is configured to absorb heat transferred by the thermoelectric cooling device.

In accordance with another aspect of the invention, the thermoelectric cooling device includes a Peltier element.

In accordance with another aspect of the invention, the heat sink device includes an active heat sink.

In accordance with another aspect of the invention, the active heat sink includes a thermoelectric cooling device.

In accordance with another aspect of the invention, the active heat sink includes at least one fan for circulating air around the housing of the electronic device.

In accordance with another aspect of the invention, at least one of the electronic device or the heat sink device includes an attachment mechanism for securing the electronic device and heat sink device together.

In accordance with another aspect of the invention, the electronic device further comprises an accessory module for supporting at least one of the electronic device and heat sink device.

In accordance with another aspect of the invention, the heat sink device is integral with the accessory module.

In accordance with another aspect of the invention, the accessory module includes at least one of a user input device, a power supply, or a speaker.

In accordance with another aspect of the invention, a surface of the heat sink device is configured to engage a surface of the electronic device to form a thermal interface for the transfer of heat from the interior of the housing to the heat sink device.

In accordance with another aspect of the invention, said electronic device is a mobile phone.

In accordance with another aspect of the invention, said electronic device includes at least one of a personal audio device, a personal video device or a personal digital assistant.

In accordance with another aspect of the invention, a device for transferring heat from an electronic device comprises an external heat sink device releasably securable to a housing of the electronic device.

In accordance with another aspect of the invention, the device comprises an antenna element, wherein the antenna element is couplable to communication circuitry of the electronic device when the heat sink device is secured to the electronic device.

In accordance with another aspect of the invention, the heat sink device includes a passive heat sink and at least one cooling fin.

In accordance with another aspect of the invention, the heat sink device includes an active heat sink.

In accordance with another aspect of the invention, the heat sink includes an attachment mechanism for releasably securing the heat sink device to the electronic device.

In accordance with another aspect of the invention, an electronic device assembly comprises an electronic device having a housing and at least one thermoelectric cooling element configured to transfer heat from an interior of the housing to an exterior of the housing, and a thermal mass releasably securable to the housing of the electronic device for absorbing heat transferred by the thermoelectric heat sink.

In accordance with another aspect of the invention, a method of dissipating heat generated by an electronic device comprises attaching a heat sink device to an exterior of a housing of the electronic device, wherein the heat sink device is configured to absorb heat from the interior of the housing and dissipate the heat to the environment.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the scope of the claims appended hereto.

Features that are described and/or illustrated with respect to one embodiment may be used in the same way or in a similar way in one or more other embodiments and/or in combination with or instead of the features of the other embodiments.

It should be emphasized that the terms “comprises” and “comprising,” when used in this specification, are taken to specify the presence of stated features, integers, steps or components but do not preclude the presence or addition of one or more other features, integers, steps, components or groups thereof.

### BRIEF DESCRIPTION OF THE DRAWINGS

FIG. 1 is a perspective view of a mobile phone.

FIG. 2 is a perspective view of an exemplary electronic device assembly including a mobile phone and an external heat sink in accordance with the invention.

FIG. 3 is a perspective view of the electronic device assembly of FIG. 2 with the external heat sink detached from the mobile phone.

FIG. 3A is an enlarged portion of FIG. 3.

FIG. 4 is a top view of another exemplary electronic device assembly including a mobile phone, an external heat sink, and an accessory module in accordance with the invention.

FIG. 5 is a side view of the electronic device assembly of FIG. 4.

### DETAILED DESCRIPTION OF EMBODIMENTS

The present invention will now be described with reference to the drawings, wherein like reference numerals are used to refer to like elements throughout.

The term “electronic equipment” includes portable radio communication equipment. The term “portable radio communication equipment,” which hereinafter is referred to as a “mobile radio terminal,” “mobile phone,” “mobile device,” or “mobile terminal” and the like, includes all equipment such as mobile telephones, pagers, communicators, i.e., electronic organizers, personal digital assistants (PDAs), smartphones, portable communication apparatus or the like. The term “electronic equipment” also may include portable digital music and/or video devices, e.g., iPod devices, mp3 players, etc.

In the present application, the invention is described primarily in the context of a mobile phone. However, it will be appreciated that the invention is not intended to be limited to a mobile phone and can be any type of electronic equipment.

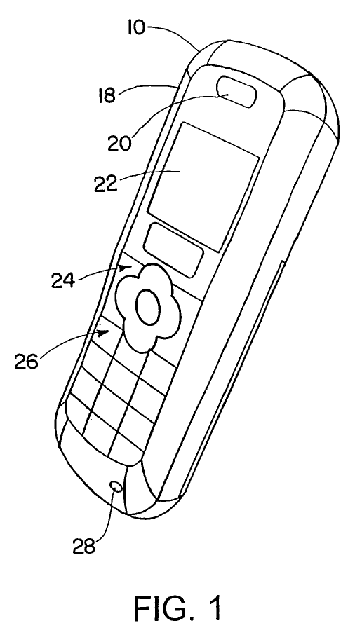

Referring now to FIG. 1, a mobile phone 10 is shown as having a “brick” or “block” design type housing 18 (sometimes referred to as a case), but it will be appreciated that other type housings, such as, for example, clam shell or slide-type housings, may be utilized without departing from the scope of the invention. The mobile phone 10 further includes a speaker 20, display 22, a navigation switch and selection/function keys or switches 24, a key pad 26, a microphone 28, and a side switch 30; these are illustrative and exemplary of parts of a typical mobile phone, but it will be appreciated that other parts that are similar or different in form and/or function may be included in the mobile phone 10. The mobile phones to which the invention pertains also may be of the types that have more or fewer functions, keys, etc., compared to those illustrated and described herein.

As will be appreciated, the mobile phone 10 may function as a conventional mobile phone. The mobile phone 10 may have additional functions and capabilities that may be developed in the future. From a conventional point of view, the display 22 displays information to a user, such as operating state, time, phone numbers, contact information, various navigational menus, etc., which facilitate and/or enable the user to utilize the various features of the mobile phone. The display also may be used to view movies, images, or to play games, for example. Part or all of the display 22 may be a touch screen type device. The navigation and function keys 24 and the keypad 26 may be conventional in that they provide for a variety of user operations. For example, one or more of the function keys and navigation device 24 may be used to navigate through a menu displayed on the display 22 to select different phone functions, profiles, settings, etc., as is conventional. The keypad 26 typically includes one or more special function keys, such as, a “call send” key for initiating or answering a call, a “call end” key for ending or hanging up a call, and dialing keys for dialing a telephone number. Other keys included in the navigation and function keys 24 and/or keypad 26 may include an on/off power key, a web browser launch key, a camera key, a voice mail key, a calendar key, etc. The side switch 30 can be configured to perform any of a wide variety of functions. The specific function of the side switch 30 is not germane to the invention as will be appreciated.

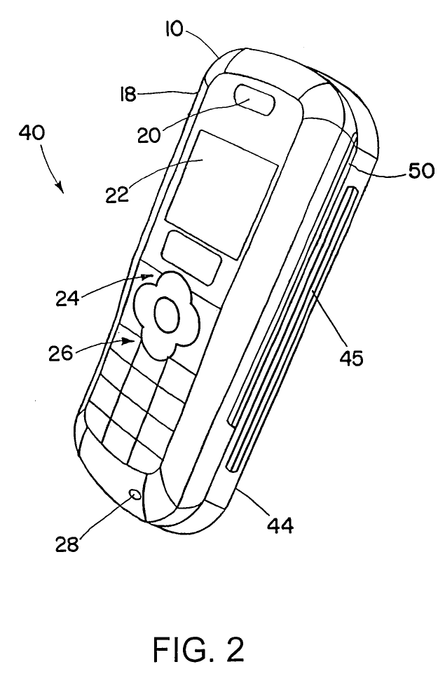

Turning to FIGS. 2-5 and initially to FIG. 2, an exemplary electronic device assembly in accordance with the invention is illustrated generally by reference numeral 40. The electronic device assembly 40 includes the mobile phone 10 and a heat sink device 44 releasably attached to the housing 18 of the mobile phone 10. The heat sink device 44 can be attached to the mobile phone 10 during periods of time when the phone 10, and more specifically processing units within the phone 10, are generating excess heat, such as when the mobile phone 10 is used for gaming, for example. The heat sink device 44 can be provided with one or more cooling fins 45 for aiding in the dissipation of heat from the heat sink device 44 to the environment. Further, and as will be described in more detail below, one or more fans or other active elements can be provided for circulating air around the housing 18 of the mobile phone 10.

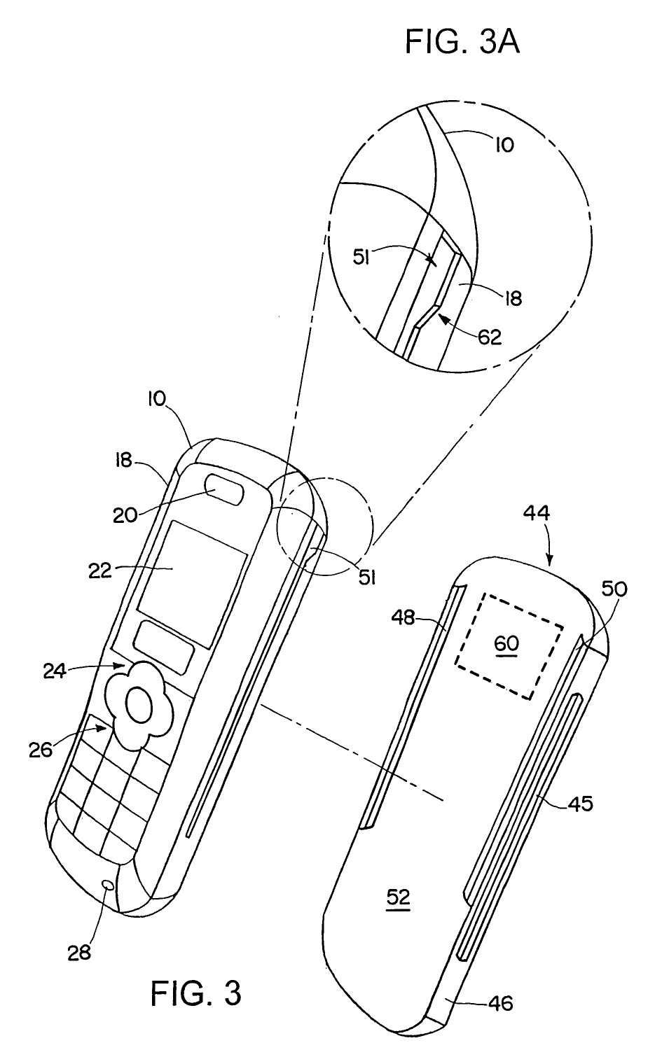

Turning to FIG. 3, the heat sink device 44 is illustrated separated (detached) from the mobile phone 10. The heat sink device 44 has a heat sink body portion 46 generally made from a material having a relatively high thermal conductivity (thermal mass). Suitable materials, for example, would include certain metals and metal alloys. As used in herein, the term passive heat sink generally refers to a thermal mass for absorbing heat.

The heat sink device 44 includes rails 48 and 50 for engaging respective sides of the mobile phone 10 for securing the heat sink device 44 thereto. As described in more detail below, suitable grooves 51 can be provided on the respective sides of the mobile phone 10 for receiving the rails 48 and 50. Alternatively, the rails 48 and 50 can be configured to compressively engage the respective sides of the mobile phone 10 sufficiently to secure the heat sink device 44 thereto.

A surface 52 of the heat sink body 46 is configured to engage the bottom or back surface of the mobile phone 10 (not shown) to form a thermal interface for the transfer of heat from the interior of the housing 18 of the mobile phone to the heat sink device 44. As will appreciated, the mobile phone 10 can be any conventional mobile phone, for example, in which case rails 48 and 50 can be configured to compressively engage the sides of the mobile phone 10. Of course, other attachment mechanisms for securing the heat sink device 44 to a conventional mobile phone can be provided.

Alternatively, the housing 18 of the mobile phone 10 can be configured to cooperate with the heat sink device 44. For example, the housing 18 can be provided with a portion thereof that is removable and/or otherwise configured to expose a surface of the mobile phone 10 that is more suitable for heat transfer than the housing 18 otherwise would be. For example, a removable cover can expose a surface adjacent a main processor of the mobile phone 10 to facilitate more efficient heat transfer.

As mentioned, the mobile phone 10 can be equipped with a groove 51 on each side of the housing 18 for receiving the rails 48 and 50 of the heat sink device 44. In such case, the heat sink device 44 can be secured to the mobile phone 10 by sliding the rails 48 and 50 into the respective groove 51 on each side of the mobile phone 10. As illustrated in FIG. 3A, the groove 51 can include a ramp surface 62 for urging the rails 48 and 50 upward as the heat sink device 44 is slid relative to the mobile phone 10. As the rails 48 and 50 are urged upward by ramp surface 62, the heat sink surface 52 engages the back surface of the mobile phone 10 to thereby form the thermal interface for absorbing heat from the mobile phone 10. The ramp surface 62 can be configured to assist in developing a prescribed state of compression between the mobile phone 10 and the heat sink device 44. Securing the heat sink device 44 to the mobile phone 10 in such a manner can facilitate more uniform and consistent heat absorption from the interior of the housing 18 of the mobile phone 10. The groove 51 can be any suitable length, and the ramp surface 62 can have any desired slope so as to ensure thermal contact between the heat sink device 44 and the mobile phone 10.

It will be appreciated that the heat sink device 44 typically will be attached to the mobile phone 10 to absorb heat from within the housing 18 during periods of time of excess heat generation. Typically, this corresponds to a gaming session, for example, a 3D gaming session when one or more processors of the phone are rendering three dimensional graphics. It will be appreciated that when using the mobile phone 10 for gaming, a user typically grasps the phone using both hands and uses respective thumbs to operate the navigational button 24 and/or keypad 26 to control the game. When grasping the phone 10 in this manner, the user not only tends to block the transfer of heat from the phone 10 to the environment (e.g., the user's hands insulate the mobile phone 10), but also may block and/or interfere with the operation of the phone's antenna. As such, during gaming the communication circuitry of the mobile phone 10 may experience difficulty connecting with a service provider's communication network. This can prevent calls and/or messages from being received by the phone, and may also decrease the performance of the mobile phone in when used in a networked gaming mode.

To decrease the likelihood of a user interfering with the operation of the communication circuitry of the mobile phone 10, an external antenna 60 is provided as part of the heat sink device 44. When the heat sink device 44 is attached to the mobile phone 10, the external antenna 60 is configured to couple with the communication circuitry of the mobile phone 10 to thereby act as the primary antenna connecting to a communications and/or gaming network. It will be appreciated that the external antenna 60 can be coupled with the communication circuitry of the mobile phone 10 in any suitable manner, such as by a suitable antenna connector associated with the external antenna 60 that connects to a respective suitable antenna connector (not shown) on the mobile phone 10.

It will be appreciated that the gaming experience of a user in real-time networked games where uplink and downlink speed in a wireless network is important can be enhanced by improved antenna performance achievable with the external antenna 60. In this regard, it will be appreciated that the antenna performance of the external antenna 60 is typically greater than the performance of a typical internal antenna associated with a mobile phone due to the larger dimensions and better grounding possible when locating the external antenna 60 with the heat sink device 44.

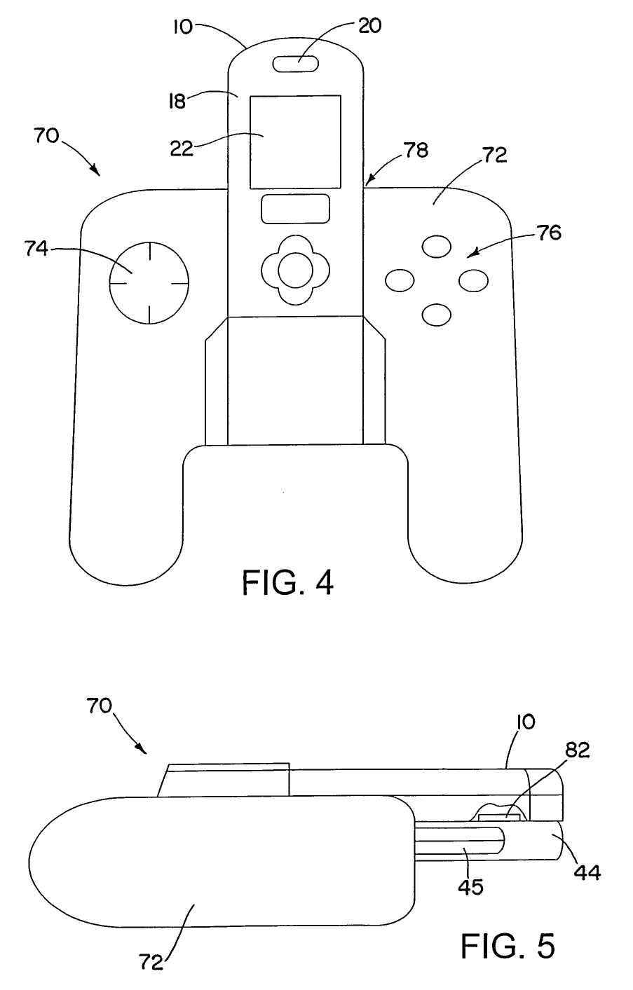

Turning to FIGS. 4 and 5, another exemplary electronic device assembly in accordance with the invention is illustrated generally by the reference numeral 70. In this embodiment the mobile phone 10 and heat sink device 44 are supported by an accessory module 72. The accessory module 72 includes a control pad 74, a plurality of buttons 76, and a slot 78 for receiving the mobile phone 10. It will be appreciated the suitable connectors on the accessory module 72 can be provided to connect the phones circuitry to the various features of the accessory module 72, such as the directional control pad 74 and/or buttons 76. The accessory module 72 can provide additional functionality such as an auxiliary power supply for supplying power to the phone 10 for extended periods of gaming. Such a power supply can be configured to not only power the mobile phone 10 but to also charge the mobile phone's 10 battery. Speakers can be provided on the accessory module for providing enhanced audio during gaming.

In the illustrated embodiment the mobile phone 10 and heat sink device 44 are attached as previously described. Together, the mobile phone 10 and heat sink device 44 are slid into the slot 78 of the accessory module 72. It will be appreciated, that the heat sink device 44 can be formed integrally with the accessory module 72, such that only the phone 10 would be slid into the accessory module 72. In such an embodiment, the rails 48 and 50 of the heat sink device 44 can serve to secure the phone to the accessory module 72. By providing the heat sink device 44 as a separate component, however, the mobile phone 10 can be used (1) alone, (2) with the heat sink device 44, or (3) with the heat sink device 44 and the accessory module 72, thereby making the electronic device assembly 70 versatile.

While providing the mobile phone 10 with the external heat sink device 44 as thus far described can be adequate for absorbing heat from the housing 18 of the mobile phone 10 under a variety of conditions, in some applications additional cooling capacity may be desired. In this regard, the heat sink device 44 can be an active heat sink employing, for example, one or more fans for circulating air around the housing 18 of the mobile phone 10 to aid in dissipating heat to the environment. The heat sink device 44 could also be equipped with a liquid cooling system for increasing its cooling capacity, for example.

Another manner in which the cooling capacity of the heat sink device 44 can be increased is by providing one or more thermoelectric cooling devices within the mobile phone 10 configured to absorb heat from the interior of the housing 18 and transfer the absorbed heat to the exterior of the housing 18. For example, in FIG. 5 a thermoelectric cooling device 82 is illustrated inside of the housing 18. The thermoelectric cooling device 82 which may be, for example a Peltier device, is positioned to absorb heat from the heat generating components of the mobile phone 10, such as the processor, and to exhaust the heat to the exterior of the housing 18. By actively transferring heat from the interior of the housing 18 to the exterior of the housing 18, the heat sink device 44 can be more effective at absorbing heat from the housing 18.

As will be appreciated, a Peltier element typically consists of semiconductors mounted successively which form P-N and N-P junctions. Each junction has a thermal contact with radiators and when current of a given polarity is supplied to the circuit, a temperature difference form between the radiators. Accordingly, one of the radiators warms and one of the radiators cools. By placing the cold side of the Peltier module near the heat generating components of the mobile phone 10, and the hot side of the Peltier device near an external surface of the mobile phone 10, heat can be transferred from the interior of the housing to the exterior by the Peltier device.

Although the invention has been shown and described with respect to certain preferred embodiments, it is understood that equivalents and modifications will occur to others skilled in the art upon the reading and understanding of the specification. The present invention includes all such equivalents and modifications, and is limited only by the scope of the following claims.

What is claimed is:

1. An electronic device assembly, comprising:
an electronic device having a housing; and
a heat sink device releasably attachable to the housing of the electronic device for absorbing heat therefrom.

2. An electronic device assembly as set forth in claim 1, wherein the electronic device includes communication circuitry, and wherein the heat sink device includes an antenna element couplable to the communication circuitry when the heat sink device is attached to the electronic device.

3. An electronic device assembly as set forth in claim 1, wherein the heat sink device includes a passive heat sink.

4. An electronic device assembly as set forth in claim 3, wherein the passive heat sink includes at least one cooling fin for dissipating heat into the environment.

5. An electronic device assembly as set forth in claim 1, further comprising a thermoelectric cooling device within the housing of the electronic device, the thermoelectric cooling device configured to transfer heat from an interior of the housing to an exterior of the housing, wherein the heat sink device is configured to absorb heat transferred by the thermoelectric cooling device.

6. An electronic device assembly as set forth in claim 5, wherein the thermoelectric cooling device includes a Peltier device.

7. An electronic device assembly as set forth in claim 1, wherein the heat sink device includes an active heat sink.

8. An electronic device assembly as set forth in claim 7, wherein the active heat sink includes a thermoelectric cooling device.

9. An electronic device assembly as set forth in claim 7, wherein the active heat sink includes at least one fan for circulating air around the housing of the electronic device.

10. An electronic device assembly as set forth in claim 1, wherein at least one of the electronic device or the heat sink device includes an attachment mechanism for securing the electronic device and heat sink device together.

11. An electronic device assembly as set forth in claim 1, further comprising an accessory module for supporting at least one of the electronic device and heat sink device.

12. An electronic device assembly as set forth in claim 11, wherein the heat sink device is integral with the accessory module.

13. A electronic device assembly as set forth in claim 11, wherein the accessory module includes at least one of a user input device, a power supply, or a speaker.

14. An electronic device assembly as set forth in claim 1, wherein a surface of the heat sink device is configured to engage a surface of the electronic device to form a thermal interface for the transfer of heat from the interior of the housing to the heat sink device.

15. The electronic device of claim 1, wherein said electronic device is a mobile phone.

16. The electronic device of claim 1, wherein said electronic device includes at least one of a personal audio device, a personal video device or a personal digital assistant.

17. A device for transferring heat from an electronic device comprising an external heat sink releasably securable to a housing of the electronic device.

18. A device as set forth in claim 17, further comprising an antenna element, wherein the antenna element is couplable to communication circuitry of the electronic device when the device is secured to the electronic device.

19. A device as set forth in claim 17, wherein the heat sink includes a passive heat sink a having at least one cooling fin.

20. A device as set forth in claim 17, wherein the heat sink includes an active heat sink.

21. A device as set forth in claim 17, further comprising an attachment mechanism for releasably securing the device to the electronic device.

22. An electronic device assembly comprising;
an electronic device having a housing and at least one thermoelectric cooling element configured to transfer heat from an interior of the housing to an exterior of the housing; and
a thermal mass releasably securable to the housing of the electronic device for absorbing heat transferred by the thermoelectric cooling element.

23. A method of cooling an electronic device comprising attaching a heat sink to an exterior of a housing of the electronic device, wherein the heat sink is configured to absorb heat from the interior of the housing and dissipate the absorbed heat to the environment.
